(19) United States
(12) Patent Application Publication
(10) Pub. No.: US 2015/0263103 A1
(43) Pub. Date: Sep. 17, 2015

(54) SEMICONDUCTOR DEVICE

(71) Applicant: Kabushiki Kaisha Toshiba, Tokyo (JP)

(72) Inventors: Yasunobu Saito, Ishikawa (JP); Hidetoshi Fujimoto, Kanagawa (JP); Akira Yoshioka, Ishikawa (JP); Takeshi Uchihara, Saitama (JP); Takaaki Yasumoto, Kanagawa (JP); Naoko Yanase, Tokyo (JP); Tasuku Ono, Ishikawa (JP)

(73) Assignee: KABUSHIKI KAISHA TOSHIBA, Tokyo (JP)

(21) Appl. No.: 14/215,257

(22) Filed: Mar. 17, 2014

(51) Int. Cl. H01L 29/205; H01L 29/51; H01L 27/06; H01L 29/778; H01L 29/20

(52) U.S. Cl. CPC H01L 29/205; H01L 29/7787; H01L 29/2003; H01L 27/0617; H01L 27/0605; H01L 29/518

(57) ABSTRACT

A semiconductor device according to an embodiment includes a first semiconductor layer including a first nitride semiconductor, a second semiconductor layer on the first semiconductor layer including a second nitride semiconductor, a source electrode, a drain electrode, a first gate electrode provided on the second semiconductor layer between the source electrode and the drain electrode having a schottky junction, a second gate electrode provided above the second semiconductor layer intervening an insulating film, provided between the source electrode and the first gate electrode, electrically connected with the first gate electrode, and a third gate electrode provided above the second semiconductor layer intervening an insulating film, provided between the drain electrode and the first gate electrode, electrically connected with the first gate electrode. A first transistor structure has a first threshold value, a second transistor structure has a second threshold value, and a third transistor structure has a third threshold value.

### CROSS-REFERENCE TO RELATED APPLICATION

This application is based upon and claims the benefit of priority from Japanese Patent Application No. 2013-059337, filed on Mar. 22, 2013, the entire contents of which are incorporated herein by reference.

### FIELD

Embodiments described herein relate generally to a semiconductor device.

### BACKGROUND

Switching elements used for switching power supplies, inverter circuits, or the like are required to have a high breakdown voltage and a low on-resistance. Switching elements employing a nitride semiconductor can improve a trade-off relation between a breakdown voltage and an on-resistance due to excellent material characteristics. Thus, the switching elements employing a nitride semiconductor are expected to be able to realize a low on-resistance and a high breakdown voltage.

As a switching element employing a nitride semiconductor, there is a high electron mobility transistor (HEMT) using an AlGaN/GaN hetero structure. Further, as one of gate electrode structures of an HEMT using an AlGaN/GaN hetero structure, there is a schottky gate electrode structure. In the schottky gate electrode structure, a gate electrode has a schottky junction on a semiconductor layer.

The HEMT of the schottky gate electrode structure does not include a gate insulating film causing a charge trapping and thus is relatively small in a variation in a threshold value. However, in the HEMT of the schottky gate electrode structure, a gate leakage current when turned off causes a problem.

### BRIEF DESCRIPTION OF THE DRAWINGS

FIG. 1 is a schematic cross-sectional view illustrating a structure of a semiconductor device of a first embodiment;

FIGS. 2A and 2B are diagrams for describing effects of the semiconductor device of the first embodiment;

FIG. 3 is a schematic cross-sectional view illustrating a structure of a semiconductor device of a second embodiment;

FIG. 4 is a schematic cross-sectional view illustrating a structure of a semiconductor device of a third embodiment;

FIG. 5 is a schematic cross-sectional view illustrating a structure of a semiconductor device of a fourth embodiment;

FIG. 6 is a schematic cross-sectional view illustrating a structure of a semiconductor device of a fifth embodiment; and

FIG. 7 is a schematic cross-sectional view illustrating a structure of a semiconductor device of a sixth embodiment.

### DETAILED DESCRIPTION

A semiconductor device of an embodiment includes a first semiconductor layer including a first nitride semiconductor; a second semiconductor layer provided on the first semiconductor layer, the second semiconductor layer including a second nitride semiconductor having a band gap larger than the first nitride semiconductor; a source electrode provided above the second semiconductor layer; a drain electrode provided above the second semiconductor layer; a first gate electrode provided on the second semiconductor layer between the source electrode and the drain electrode, the first gate electrode having a schottky junction with the second semiconductor layer; a second gate electrode provided above the second semiconductor layer intervening an insulating film, the second gate electrode provided between the source electrode and the first gate electrode, the second gate electrode electrically connected with the first gate electrode; and third gate electrode provided above the second semiconductor layer intervening an insulating film, the third gate electrode provided between the drain electrode and the first gate electrode, the third gate electrode electrically connected with the first gate electrode. And a first transistor structure controlled by the first gate electrode has a first threshold value, a second transistor structure controlled by the second gate electrode has a second threshold value, and a third transistor structure controlled by the third gate electrode has a third threshold value.

In this specification, “a threshold value of a transistor is low” means that a threshold value is relatively in a negative direction, and “a threshold value of a transistor is high” means that a threshold value is relatively in a positive direction.

For example, when threshold values of two normally-on transistors having a negative threshold value are compared, “a threshold value is low” means that an absolute value is large, and “a threshold value is high” means that an absolute value is small.

Further, for example, when threshold values of two normally-off transistors having a positive threshold value are compared, “a threshold value is low” means that an absolute value is small, and “a threshold value is high” means that an absolute value is large.

### First Embodiment

A semiconductor device of the present embodiment includes a first semiconductor layer including a first nitride semiconductor, a second semiconductor layer that is formed on the first semiconductor layer and includes a second nitride semiconductor having a band gap larger than the first nitride semiconductor, a source electrode that is formed on or above the second semiconductor layer, and a drain electrode that is formed on the second semiconductor layer. The semiconductor device further includes a first gate electrode that is formed on or above the second semiconductor layer between the source electrode and the drain electrode and has a schottky junction with the second semiconductor layer, a second gate electrode that is formed above the second semiconductor layer between the source electrode and the first gate electrode through an insulating film and electrically connected with the first gate electrode, and a third gate electrode that is formed above the second semiconductor layer between the drain electrode and the first gate electrode through an insulating film and electrically connected with the first gate electrode. And a first transistor structure controlled by the first gate electrode has a first threshold value, a second transistor structure controlled by the second gate electrode has a second threshold value, and a third transistor structure controlled by the third gate electrode has a third threshold value.

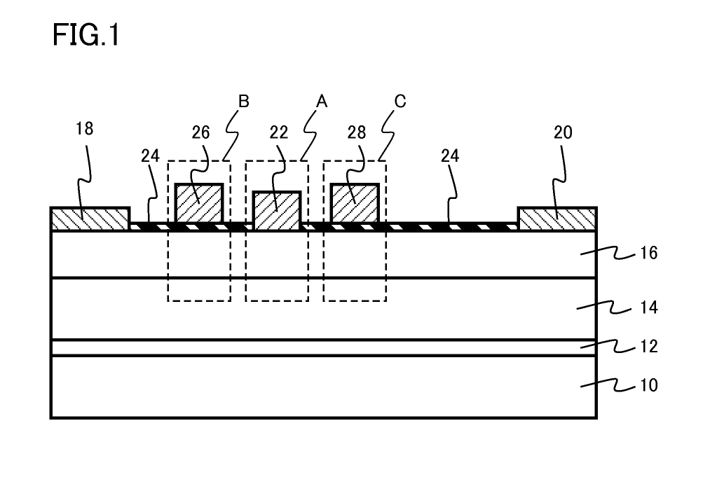

FIG. 1 is a schematic cross-sectional view illustrating a structure of a semiconductor device of the present embodiment. The semiconductor device of the present embodiment is a normally-on HEMT. An HEMT using a hetero junction is high in channel mobility, thus can reduce an on-resistance, and is suitable for semiconductor devices for power electronics. Further, high channel mobility is suitable for a high-frequency operation as well.

The semiconductor device of the present embodiment includes a substrate 10, a buffer layer 12 formed on the substrate 10, a first semiconductor layer 14 formed on the buffer layer 12, and a second semiconductor layer 16 formed on the first semiconductor layer 14.

For example, the substrate 10 is made of silicon (Si). Besides silicon, for example, sapphire (Al₂O₃) or silicon carbide (SiC) can be applied.

The buffer layer 12 has a function of mitigating a lattice mismatch between the substrate 10 and the first semiconductor layer 14. For example, the buffer layer 12 is formed to have a multi-layer structure of aluminum gallium nitride (AlₓGa₁₋ₓN (0<X<1)).

The first semiconductor layer 14 is an active layer (a channel layer), and the second semiconductor layer 16 is a barrier layer (an electron supply layer). The first semiconductor layer 14 formed of a first nitride semiconductor. The second semiconductor layer 16 is formed of a second nitride semiconductor having a band gap larger than that of the first nitride semiconductor forming the first semiconductor layer 14.

For example, a first nitride semiconductor used to form the first semiconductor layer 14 is an undoped gallium nitride or an aluminum gallium nitride (AlₓGa₁₋ₓN (0≦X≦1)). The first nitride semiconductor may be an n-type or a p-type. For example, the film thickness of the first semiconductor layer 14 is 0.5 to 3 μm.

Further, for example, a second nitride semiconductor used to form the second semiconductor layer 16 is an n-type aluminum gallium nitride (Al_{y}Ga_{1-y}N (0<Y≦1, X<Y)). The second nitride semiconductor may be an undoped one. For example, the film thickness of the second semiconductor layer 16 is 20 to 50 nm.

Further, the first and second nitride semiconductors are not necessarily limited to the above materials, and any other nitride semiconductor can be applied.

A hetero junction interface is formed between the first semiconductor layer 14 and the second semiconductor layer 16. When a transistor is turned on, two-dimensional electron gas is formed in the hetero junction interface and serves as a carrier.

A source electrode 18 and a drain electrode 20 are formed on the second semiconductor layer 16. The source electrode 18 and the drain electrode 20 are, for example, a metallic electrode, and the metallic electrode is an electrode made primarily of aluminum (Al). An ohmic contact is formed between each of the source electrode 18 and the drain electrode 20 and the second semiconductor layer 16. For example, the distance between the source electrode 18 and the drain electrode 20 is about 10 μm.

Then, a first gate electrode 22 is formed on the second semiconductor layer 16 between the source electrode 18 and the drain electrode 20. The first gate electrode 22 has a schottky junction on the second semiconductor layer 16. For example, the gate length of the first gate electrode is 1 μm.

For example, the first gate electrode 22 is a metallic electrode. For example, the metallic electrode is a nickel (Ni) electrode, a titanium (Ti) electrode, or platinum (Pt). The metallic electrode may have a metallic alloy thereof or may have a stacked structure thereof. Further, in order to reduce resistance of a gate electrode, gold (Au) having low resistance may be stacked thereon.

Further, a second gate electrode 26 is formed above the second semiconductor layer 16 between the source electrode 18 and the first gate electrode 22 through an insulating film 24. The second gate electrode 26 is electrically connected with the first gate electrode 22. For example, the gate length of the second gate electrode 26 is 1 μm.

Further, a third gate electrode 28 is formed above the second semiconductor layer 16 between the drain electrode 20 and the first gate electrode 22 through the insulating film 24. The third gate electrode 28 is electrically connected with the first gate electrode 22. For example, the gate length of the third gate electrode 28 is 1 μm.

The insulating film 24 functions as a gate insulating film of the second and third gate electrodes 26 and 28. For example, the insulating film 24 is a silicon nitride film that is easily formed as a material and has high stability. However, the insulating film 24 is not limited to a silicon nitride film, and for example, any other material such as a silicon oxide film, a silicon oxide nitride film, or an aluminum oxide film can be applied.

For example, the second gate electrode 26 and the third gate electrode 28 are a metallic electrode. For example, the metallic electrode is a nickel (Ni) electrode, a titanium (Ti) electrode, or platinum (Pt). The metallic electrode may have a metallic alloy thereof or may have a stacked structure thereof. Further, in order to reduce resistance of a gate electrode, gold (Au) having low resistance may be stacked thereon.

In FIG. 1, a frame line A of a dotted line represents a transistor structure controlled by the first gate electrode 22, a frame line B of a dotted line represents a transistor structure controlled by the second gate electrode 26, and a frame line C of a dotted line represents a transistor structure controlled by the third gate electrode 28.

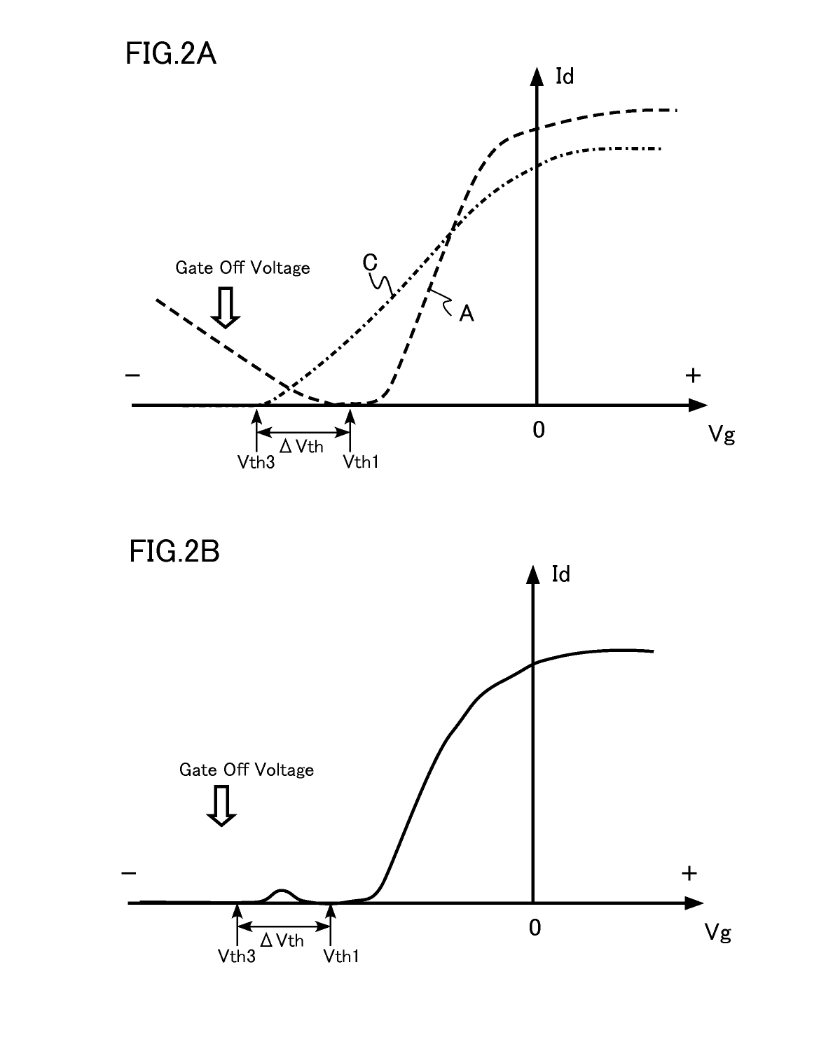

FIGS. 2A and 2B are diagrams for describing effects of the semiconductor device of the present embodiment. FIG. 2A is an explanatory diagram illustrating gate voltage dependency of a drain current in the transistor structure controlled by the first gate electrode 22 and the transistor structure controlled by the third gate electrode 28 of the present embodiment. FIG. 2B is an explanatory diagram illustrating gate voltage dependency of a drain current in an HEMT of the present embodiment. In both FIGS. 2A and 2B, a horizontal axis represents a gate voltage, and a vertical axis represents a drain current.

In FIG. 2A, characteristics of the transistor structure controlled by the first gate electrode 22 (which is hereinafter referred to as a “structure A” as well) are represented by a dotted line A. In the structure A, a first threshold value (Vth1) has a negative value. In other words, the structure A is a normally-on transistor. The structure A is a transistor of a schottky gate electrode structure.

In the structure A, when the gate voltage exceeds the first threshold value (Vth1) and increases in the positive direction, the drain current increases. However, when the gate voltage exceeds the first threshold value (Vth1) and increases in the negative direction, the drain current that does not flow flows again. In other words, after pinch off, when an absolute value of a negative gate voltage increases, the drain current turns into an increase. This current is a gate leakage current flowing between the gate electrode and the drain electrode. It is difficult to suppress the gate leakage current only by the structure A in which the gate electrode is formed by the schottky junction.

Meanwhile, in FIG. 2A, characteristics of the transistor structure controlled by the third gate electrode 28 (which is hereinafter referred to as a “structure C” as well) are represented by an alternate long and short dash line C. In the structure C, a third threshold value (Vth3) has a negative value. In other words, the structure A is a normally-on transistor. Further, the structure B is a transistor of a metal insulator semiconductor (MIS) gate electrode structure in which an insulating layer is formed between a gate electrode and a semiconductor layer.

In the structure C, when the gate voltage exceeds the third threshold value (Vth3) and increases in the positive direction, the drain current increases. However, since the insulating film 24 is formed between the third gate electrode 28 and the second semiconductor layer 16, even when the gate voltage exceeds the third threshold value (Vth3) and increases in the negative direction, a very small gate leakage current flows between the gate electrode 28 and the drain electrode 20.

Further, in FIG. 2A, although not illustrated, the transistor structure controlled by the second gate electrode 26 (which is hereinafter referred to as a “structure B” as well) is a transistor of an MIS gate electrode structure and identical in characteristics to the structure C.

The HEMT of the present embodiment has a transistor structure in which the structure B of the MIS gate electrode structure, the structure A of the schottky gate electrode structure, and the structure C of the MIS gate electrode structure are connected in series between the source electrode 18 and the drain electrode 20. Thus, the gate voltage dependency of the drain current of the HEMT becomes a characteristic in which characteristics of the structure A and the structure C of FIG. 2A overlap as illustrated in FIG. 2B under the assumption that the structure B is identical in characteristics to the structure C. In other words, the drain current of the whole HEMT is specified by the drain current of one of the structure A and the structure C that is smaller in the drain current.

In the present embodiment, the first threshold value (Vth1) is higher than the second and third threshold values (Vth2 and Vth3). Thus, the first threshold value (Vth1) and the third threshold value (Vth3) are in a magnitude relation illustrated in FIGS. 2A and 2B.

In view of the whole HEMT, when the gate voltage is 0 V, the drain current flows, and it enters an on-state as illustrated in FIG. 2B. Then, when the gate voltage increases from 0 V in the negative direction, it enters a pitch-off state at the first threshold value (Vth1) of the structure A of the schottky gate electrode structure, and the transistor is turned off. Further, when the gate voltage increases in the negative direction, the gate leakage current flows to the first gate electrode 22 of the schottky gate electrode structure.

Meanwhile, the structure C of the MIS gate electrode structure enters the pinch-off state at the third threshold value (Vth3) that is at the negative side further than in the structure A. For this reason, in the whole HEMT, even when the gate voltage increases in the negative direction, at the negative side further than the third threshold value (Vth3), the gate leakage current that flows to the first gate electrode 22 is interrupted by the structure C. As a result, the gate leakage current is suppressed.

As described above, in the HEMT of the present embodiment, the schottky gate electrode structure and the MIS gate electrode structure are connected in series, and thus it is possible to suppress the gate leakage current. Further, the threshold value of the whole HEMT is specified by the first threshold value (Vth1) of the schottky gate electrode structure in which a threshold value is unlikely to vary rather than the second and third threshold values (Vth2 and Vth3) of the MIS gate electrode structure in which a threshold value is likely to vary, for example, due to trapping of charges in an interface state.

Thus, even when the threshold values of the second and third threshold values (Vth2 and Vth3) vary, influence thereof is hardly observed in the whole HEMT. Thus, the gate leakage current is suppressed, and the HEMT that is small in a threshold value variation is implemented.

Further, it is preferable that the second and third threshold values (Vth2, Vth3) be higher than voltages (white arrows in FIGS. 2A and 2B) applied to the first to third gate electrodes 22, 26, and 28 when turned off as illustrated in FIGS. 2A and 2B. In this case, it is because when the HEMT is turned off, the pinch-off states of the structure B and the structure C are maintained, and the gate leakage current can be further suppressed.

Further, it is preferable that an absolute value (ΔVth in FIGS. 2A and 2B) of the difference between the second and third threshold values (Vth2 and Vth3) and the first threshold value (Vth1) is 0.1 V or more and 1 V or less. In the case in which the absolute value is less than 0.1 V, when the second and third threshold values (Vth2 and Vth3) vary, the threshold value is higher than the first threshold value (Vth1), and the threshold value of the whole HEMT is likely to be specified by the second or third threshold value (Vth2 or Vth3) that easily varies. Further, in the case in which the absolute value is larger than 1 V, the gate leakage current of the schottky gate electrode structure (the structure A) is likely to be insufficiently interrupted by the MIS gate electrode structure (the structure B and C). In other words, when the second and third threshold values (Vth2 and Vth3) are too apart from the first threshold value (Vth1) and the gate voltage is shifted to the negative side further than the first threshold value (Vth1), pinch-off by the structures B and C does not occur for a while, and the gate leakage current may be insufficiently interrupted.

Further, in the HEMT of the present embodiment, the threshold values of the schottky gate electrode structure, and the MIS gate electrode structure, that is, the first to third threshold values can be calculated by an analytical or numerical calculation as an element structure, a material, impurity density, and the like are given.

Further, it is preferable that the second and third gate electrodes 26 and 28 are longer in the gate length than the first gate electrode 22. In this case, interruption characteristics of the structures B and C which are the MIS gate electrode structure are improved, and interruption characteristics of the gate leakage current are improved.

### Second Embodiment

A semiconductor device of the present embodiment is identical to that of the first embodiment except that the first gate electrode has a structure in which a third nitride semiconductor of a p-type and metal are stacked. Therefore, the description of the contents overlapped with those of the first embodiment is omitted.

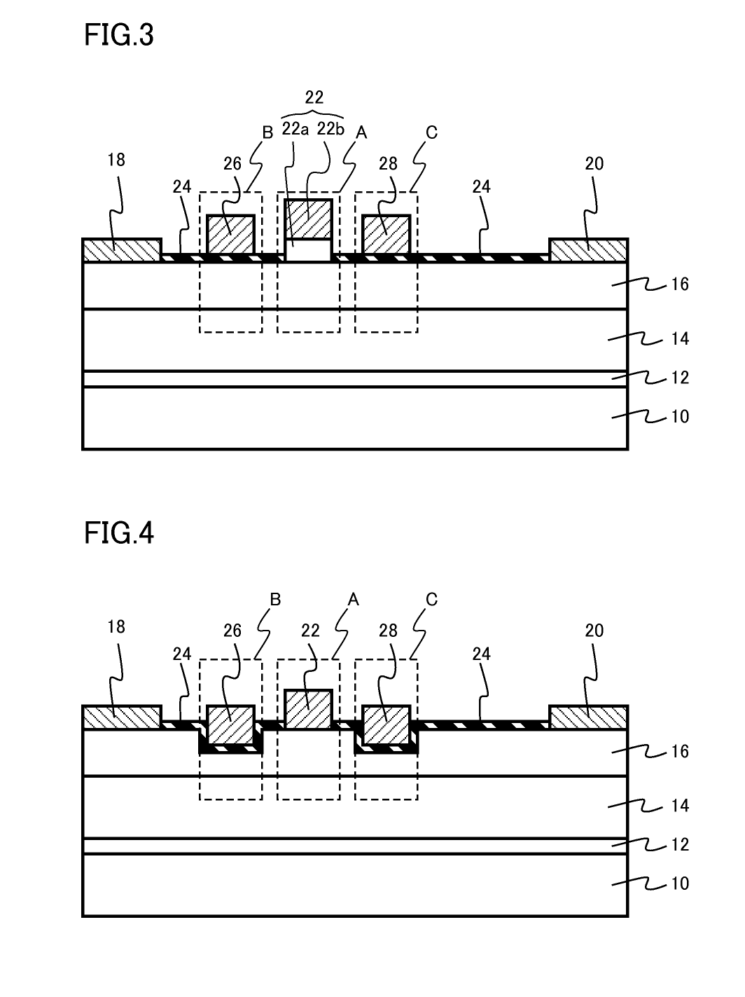

FIG. 3 is a schematic cross-sectional view illustrating a structure of a semiconductor device of the present embodiment. As illustrated in FIG. 3, in the semiconductor device of the present embodiment, the first gate electrode has a structure in which a third nitride semiconductor 22a of a p-type and metal 22b are stacked.

In other words, a transistor structure (a structure A) controlled by the first gate electrode represented by a frame line A of a dotted line has a so-called junction-type gate electrode structure. The junction-type gate electrode structure does not include a gate insulating film causing a charge trapping, similarly to the schottky gate electrode structure and is small in a threshold value variation.

The third nitride semiconductor 22a of the p-type is made of a gallium nitride (GaN) containing, for example, magnesium (Mg) as a p-type impurity.

According to the present embodiment, potential of the first semiconductor layer (the channel layer) 14 is increased by the third nitride semiconductor 22a of the p-type. Thus, it is possible to easily shift the first threshold value (Vth1) of the structure A in the positive direction. In other words, it is easy to increase the first threshold value (Vth1). Thus, it is easy to form a normally-off HEMT.

Further, similarly to the first embodiment, the gate leakage current is suppressed, and an HEMT that is small in a threshold value variation is implemented.

### Third Embodiment

A semiconductor device of the present embodiment is identical to that of first embodiment except that the film thickness of the second semiconductor layer directly below the second and third gate electrodes is smaller than the film thickness of the second semiconductor layer directly below the first gate electrode. Therefore, the description of the contents overlapped with those of the first embodiment is omitted.

FIG. 4 is a schematic cross-sectional view illustrating a structure of a semiconductor device of the present embodiment. As illustrated in FIG. 4, in the semiconductor device of the present embodiment, the film thickness of the second semiconductor layer 16 directly below the second and third gate electrodes 26 and 28 is smaller than the film thickness of the second semiconductor layer 16 directly below the first gate electrode 22.

In other words, a transistor structure (a structure B) controlled by the second gate electrode 26 represented by a frame line B of a dotted line and a transistor structure (a structure C) controlled by the third gate electrode 28 represented by a frame line C of a dotted line have a so-called recess structure.

According to the present embodiment, as the structure B and the structure C have the recess structure, it is easy to increase the threshold values of the structure B and the structure C which are the MIS gate electrode structure. Further, the threshold value is easily adjusted by changing the depth of the recess structure.

Thus, the difference between the first threshold value (Vth1) of the structure A and the second and third threshold values (Vth2 and Vth3) of the structures B and C is easily adjusted to an optimal value. Particularly, the first threshold value (Vth1) and the second and third threshold values (Vth2 and Vth3) are easily approximated.

Thus, an HEMT in which the gate leakage current is more easily suppressed is implemented. Further, similarly to the first embodiment, an HEMT that is small in a threshold value variation is implemented.

### Fourth Embodiment

A semiconductor device of the present embodiment is identical to that of second embodiment except that the film thickness of the second semiconductor layer directly below the second and third gate electrodes is smaller than the film thickness of the second semiconductor layer directly below the first gate electrode. Therefore, the description of the contents overlapped with those of the second embodiment is omitted.

FIG. 5 is a schematic cross-sectional view illustrating a structure of a semiconductor device of the present embodiment. As illustrated in FIG. 5, in the semiconductor device of present embodiment, the film thickness of the second semiconductor layer 16 directly below the second and third gate electrodes 26 and 28 is smaller than the film thickness of the second semiconductor layer 16 directly below the first gate electrode 22.

In other words, a transistor structure (a structure B) controlled by the second gate electrode 26 represented by a frame line B of a dotted line and a transistor structure (a structure C) controlled by the third gate electrode 28 represented by a frame line C of a dotted line have a so-called recess structure.

According to the present embodiment, as the structure B and the structure C have the recess structure, it is easy to increase the threshold values of the structure B and the structure C which are the MIS gate electrode structure. Further, the threshold value is easily adjusted by changing the depth of the recess structure. Thus, the difference between the first threshold value (Vth1) of the structure A and the second and third threshold values (Vth2 and Vth3) of the structures B and C is easily adjusted to an optimal value. Particularly, the first threshold value (Vth1) and the second and third threshold values (Vth2 and Vth3) are easily approximated.

Thus, an HEMT in which the gate leakage current is more easily suppressed is implemented. Further, similarly to the second embodiment, an HEMT that is small in a threshold value variation is implemented.

### Fifth Embodiment

A semiconductor device of the present embodiment is identical to that of first embodiment except that a semiconductor region containing fluorine or chlorine is formed in the second semiconductor layer directly below the second and third gate electrodes. Therefore, the description of the contents overlapped with those of the first embodiment is omitted.

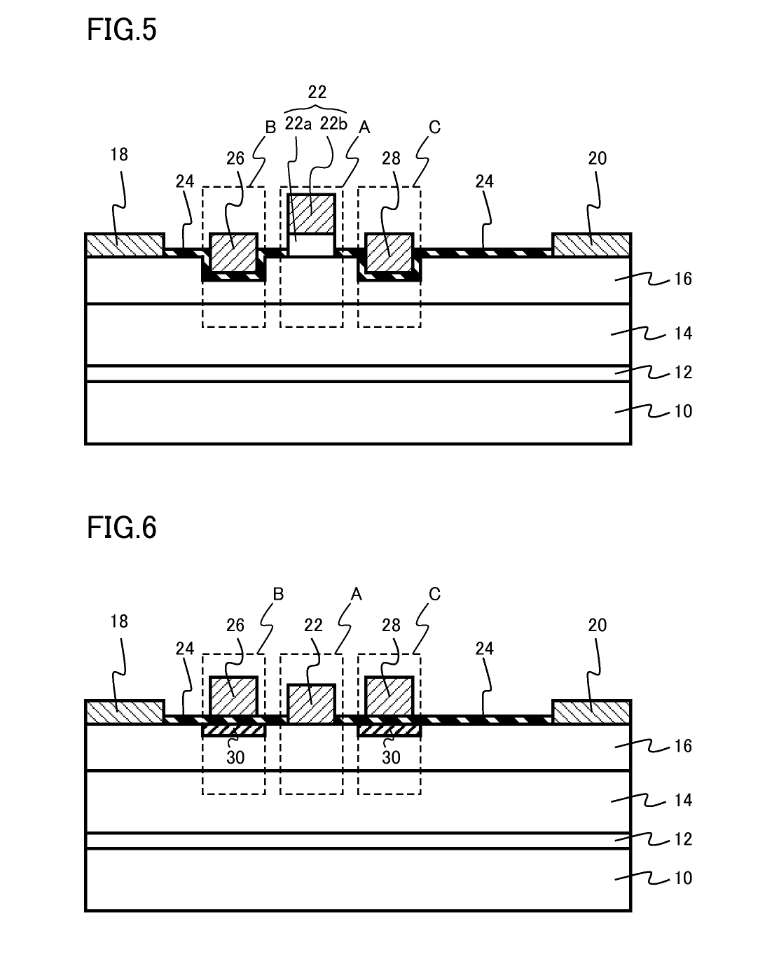

FIG. 6 is a schematic cross-sectional view illustrating a structure of a semiconductor device of the present embodiment. As illustrated in FIG. 6, in the semiconductor device of the present embodiment, a semiconductor region 30 containing fluorine (F) or chlorine (Cl) is formed in the second semiconductor layer 16 directly below the second and third gate electrodes 26 and 28.

For example, the semiconductor region 30 can be formed by ion-implanting fluorine (F) or chlorine (Cl) into the second semiconductor layer 16.

According to the present embodiment, as the semiconductor region 30 is formed, it is possible to increase the threshold values of the structure B and the structure C that are the MIS gate electrode structure. In other words, as fluorine (F) or chlorine (Cl) that is a negative ion is introduced into the second semiconductor layer 16, an operation of negating an electric field is performed, and it is possible to increase a threshold value.

Further, the threshold value is easily adjusted by changing the amount of fluorine (F) or chlorine (Cl). Thus, the difference between the first threshold value (Vth1) of the structure A and the second and third threshold values (Vth2 and Vth3) of the structures B and C is easily adjusted to an optimal value. Particularly, the first threshold value (Vth1) and the second and third threshold values (Vth2 and Vth3) are easily approximated.

Thus, an HEMT in which the gate leakage current is more easily suppressed is implemented. Further, similarly to the first embodiment, an HEMT that is small in a threshold value variation is implemented.

### Sixth Embodiment

A semiconductor device of the present embodiment is identical to that of second embodiment except that a semiconductor region containing fluorine or chlorine is formed in the second semiconductor layer directly below the second and third gate electrodes. Therefore, the description of the contents overlapped with those of the second embodiment is omitted.

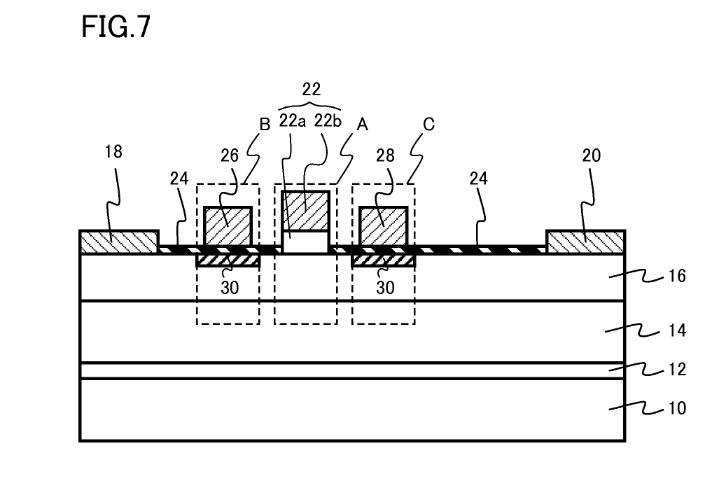

FIG. 7 is a schematic cross-sectional view illustrating a structure of a semiconductor device of the present embodiment. As illustrated in FIG. 7, in the semiconductor device of present embodiment, a semiconductor region 30 containing fluorine (F) or chlorine (Cl) is formed in the second semiconductor layer 16 directly below the second and third gate electrodes 26 and 28.

For example, the semiconductor region 30 can be formed by ion-implanting fluorine (F) or chlorine (Cl) into the second semiconductor layer 16.

According to the present embodiment, as the semiconductor region 30 is formed, it is possible to increase the threshold values of the structure B and the structure C that are the MIS gate electrode structure. In other words, as fluorine (F) or chlorine (Cl) that is a negative ion is introduced into the second semiconductor layer 16, an operation of negating an electric field is performed, and it is possible to increase a threshold value.

Further, the threshold value is easily adjusted by changing the amount of fluorine (F) or chlorine (Cl). Thus, the difference between the first threshold value (Vth1) of the structure A and the second and third threshold values (Vth2 and Vth3) of the structures B and C is easily adjusted to an optimal value. Particularly, the first threshold value (Vth1) and the second and third threshold values (Vth2 and Vth3) are easily approximated.

Thus, an HEMT in which the gate leakage current is more easily suppressed is implemented. Further, similarly to the second embodiment, an HEMT that is small in a threshold value variation is implemented.

The above embodiments have been described with reference to the cross-sectional structure in which the first to third gate electrodes are physically separated. However, the first to third gate electrodes may be physically integrated.

Further, the above embodiments have been described using an HEMT as an example of a semiconductor device, but the present disclosure can be applied to any field-effect transistor (FET) other than the HEMT. Further, an integrated circuit (IC) in which an FET is combined with an element such as a schottky barrier diode is included in the scope of a semiconductor device of present disclosure as well.

While certain embodiments have been described, these embodiments have been presented by way of example only, and are not intended to limit the scope of the inventions. Indeed, a semiconductor device described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A semiconductor device, comprising:
a first semiconductor layer including a first nitride semiconductor;
a second semiconductor layer provided on the first semiconductor layer, the second semiconductor layer including a second nitride semiconductor having a band gap larger than the first nitride semiconductor;
a source electrode provided above the second semiconductor layer;
a drain electrode provided above the second semiconductor layer;
a first gate electrode provided on the second semiconductor layer between the source electrode and the drain electrode, the first gate electrode having a schottky junction with the second semiconductor layer;
a second gate electrode provided above the second semiconductor layer intervening an insulating film, the second gate electrode provided between the source electrode and the first gate electrode, the second gate electrode electrically connected with the first gate electrode; and
a third gate electrode provided above the second semiconductor layer intervening an insulating film, the third gate electrode provided between the drain electrode and the first gate electrode, the third gate electrode electrically connected with the first gate electrode,
wherein, a first transistor structure has a first threshold value, a second transistor structure has a second threshold value, and a third transistor structure has a third threshold value.

2. The device according to claim 1,
wherein the first threshold value is higher than the second and third threshold values.

3. The device according to claim 1,
wherein a film thickness of the second semiconductor layer directly below the second and third gate electrodes is smaller than a film thickness of the second semiconductor layer directly below the first gate electrode.

4. The device according to claim 1,
wherein a semiconductor region containing fluorine or chlorine is formed in the second semiconductor layer directly below the second and third gate electrodes.

5. The device according to claim 1,
wherein the second and third threshold values are higher than voltages applied to the first to third gate electrodes when turned off.

6. The device according to claim 1,
wherein an absolute value of a difference between the second and third threshold values and the first threshold value is 1 V or less.

7. The device according to claim 1,
wherein the second and third gate electrodes are larger in a gate length than the first gate electrode.

8. The device according to claim 1,
wherein the first nitride semiconductor is made of AlₓGa₁₋ₓN (0≦X≦1), and the second nitride semiconductor is made of Al_{y}Ga_{1-y}N (0<Y≦1, X<Y).

9. The device according to claim 1,
wherein the insulating film is a silicon nitride film.

10. The device according to claim 1,
wherein an ohmic contact is formed between the source electrode and the second semiconductor layer and between the drain electrode and the second semiconductor layer.

11. A semiconductor device, comprising:
a first semiconductor layer including a first nitride semiconductor;
a second semiconductor layer provided on the first semiconductor layer, the second semiconductor layer including a second nitride semiconductor having a band gap larger than the first nitride semiconductor;
a source electrode provided above the second semiconductor layer;
a drain electrode provided above the second semiconductor layer;
a first gate electrode provided on the second semiconductor layer between the source electrode and the drain electrode, the first gate electrode having a structure in which a third nitride semiconductor of a p-type and metal are stacked;
a second gate electrode provided above the second semiconductor layer intervening an insulating film, the second gate electrode provided between the source electrode and the first gate electrode, the second gate electrode electrically connected with the first gate electrode; and
a third gate electrode provided above the second semiconductor layer intervening an insulating film, the third gate electrode provided between the drain electrode and the first gate electrode, the third gate electrode electrically connected with the first gate electrode,
wherein, a first transistor structure has a first threshold value, a second transistor structure has a second threshold value, and a third transistor structure has a third threshold value.

12. The device according to claim 11,
wherein the first threshold value is higher than the second and third threshold values.

13. The device according to claim 11,
wherein a film thickness of the second semiconductor layer directly below the second and third gate electrodes is smaller than a film thickness of the second semiconductor layer directly below the first gate electrode.

14. The device according to claim 11,
wherein a semiconductor region containing fluorine or chlorine is formed in the second semiconductor layer directly below the second and third gate electrodes.

15. The device according to claim 11,
wherein the second and third threshold values are higher than voltages applied to the first to third gate electrodes when turned off.

16. The device according to claim 11,
wherein an absolute value of a difference between the second and third threshold values and the first threshold value is 1 V or less.

17. The device according to claim 11,
wherein the second and third gate electrodes are larger in a gate length than the first gate electrode.

18. The device according to claim 11,
wherein the first nitride semiconductor is made of AlₓGa₁₋ₓN (0≦X≦1), the second nitride semiconductor is made of Al_{y}Ga_{1-y}N (0<Y≦1, X<Y), and the third nitride semiconductor is made of Al_{z}Ga_{1-z}N (0≦Z≦1).

19. The device according to claim 11,
wherein the insulating film is a silicon nitride film.

20. The device according to claim 11,
wherein an ohmic contact is formed between the source electrode and the second semiconductor layer and between the drain electrode and the second semiconductor layer.
